(19) United States
(12) Patent Application Publication
(10) Pub. No.: US 2006/0057743 A1
(43) Pub. Date: Mar. 16, 2006

(54) Spintronic device having a carbon nanotube array-based spacer layer and method of forming same

(76) Inventors: Arthur J. Epstein, Bexley, OH (US); Stephen J. Etzkorn, Woodbury, MN (US)

Correspondence Address: Richard J. Minnich, Esq.;Fay, Sharpe, Fagan, Minnich & McKee, LLP, Seventh Floor, 1100 Superior Avenue, Cleveland, OH, 44114-2518, US

(21) Appl. No.: 11/086,073

(22) Filed: Mar. 22, 2005

Related U.S. Application Data
(60) Provisional application No. 60/555,108, filed on Mar. 22, 2004.

(51) Int. Cl. G11B 5/33; H01L 21/00

(52) U.S. Cl. 438/3; 360/324

(57) ABSTRACT

This invention relates to spintronic devices—and electronic devices comprising them, such as spin valves, spin tunnel junctions and spin transistors—which utilize a layer comprised of an array of aligned carbon nanontubes. A spintronic device includes, a bottom electrode, a first ferromagnetic layer, a CNT array, a second ferromagnetic layer and a top electrode.

This application claims priority to and the benefit of U.S. Provisional Application No. 60/555,108, filed Mar. 22, 2004, which application is incorporated herein by reference in its entirety.

This work is supported by U.S. Department of Energy Grant No. DE-FG02-01 ER45931, U.S. Defense Advance Projects Research Agency (DARPA) through Office of Naval Research (ONR) (Grant No. N00014-O₂-1-0593), and U.S. Army Research Office (ARO) (Grant No. DAAD 19-01-1-0562).

### TECHNICAL FIELD OF THE INVENTION

This invention relates to spintronic devices—and electronic devices comprising them, such as spin valves, spin tunnel junctions and spin transistors—which utilize a layer comprised of an array of aligned carbon nanotubes.

### BACKGROUND

Byway of background, substantial progress recently has been made in spintronics—an emerging field of microelectronics that exploits spin of electrons to control charge transport and light emission. Addition of the spin degree of freedom to conventional electronics enables enhanced performance including increased processing speed, higher information density, nonvolatile data storage, and lower power consumption. See, S. A. Wolf, D. D. Awschalom, R. A. Buhrman, J. M. Daughton, S. von Molnar, M. L. Roukes, A. Y. Chtchelkanova, and D. M. Treger, Spintronics: A Spin-Based Electronics Vision for the Future, Science 294, 1488-1495 (2001), which is incorporated herein by reference in its entirety. Magnetic/nonmagnetic hybrid systems consisting of spin-polarized ferromagnetic metallic layers separated by a nonmagnetic layer (spin-valve) are examples of spintronic devices. Extensions to magnetic semiconductor based spin valves and spin tunnel junctions, and related spin light-emitting diodes, are promising embodiments of spintronics.

The initial interest in spin-control device functionality was raised by a 1988 report on giant magnetoresistance for hybrid systems. See, M. N. Baibich, J. M. Broto, A. Fert, F. Nguyen Van Dau, and F. Petroff, Giant Magnetoresistance of (001)Fe/(001)Cr Magnetic Superlattices, Phys. Rev. Lett. 61, 2472-2475 (1988); and, G. Binasch, P. Grunberg, F. Saurenbach, W. Zinn, Enhanced Magnetoresistance in Layered Magnetic Structures with Antiferromagnetic Interlayer Exchange, Phys. Rev. B 39, 4828-4830 (1989), both of which are incorporated herein by reference in their entirety. These pioneering experiments and many subsequent studies showed that large relative variations in magnetoresistance may be achieved (up to 100%). See, A. Barthelemy, A. Fert, F. Petroff, in: K. H. J. Buschow (Ed.), Handbook of Magnetic Materials, vol. 12, Elsevier, Amsterdam, p. 3, 1999; and, J. S. Moodera and G. Mathon, Spin Polarized Tunneling in Ferromagnetic Junctions, J. Magn. Magn. Mater. 200, 248-273 (1999), both of which are incorporated herein by reference in their entirety. Giant magnetoresistance is observed in different structures that may have different microscopic mechanisms. However, common features in structures exhibiting giant magnetoresistance are high spin polarization of electrons in the magnetic portion and the preservation of spin-coherence during electron transfer between interacting magnetic components. See, M. Ziese, M. J. Thornton (Eds.), Spin Electronics, Springer, Berlin, 2001; and, E. Hirota, H. Sakakima, K. Inomata, Giant Magneto-Resistance Devices, Springer, Berlin, 2002, both of which are incorporated herein by reference in their entirety.

Since the inception of spintronic devices, many advancements have been made to the design and composition of the ferromagnetic layers. One of the first improvements was the development of a pinned ferromagnet design. In this structure, the simple ferromagnetic layer is replaced by an antiferromagnetic (AFM) layer such as iron manganese (FeMn) topped by a ferromagnetic layer such as cobalt (Co) wherein the ferromagnetic (FM) layer is in direct contact with the nonmagnetic spacer layer. The effect of the antiferromagnetic layer is to increase the coercive field of the ferromagnetic layer it is in contact with, and thus increase the effective switching field of the device. The increase in coercive field is a result of a phenomenon known as exchange bias. This type of structure is desirable in that it provides a broader region between the low and high resistance states. Thus, a typical spintronic device employing a pinned ferromagnetic layer may have the following structure: FeMn/Co/Al₂O₃/Co. In this example, both ferromagnetic layers are cobalt, the antiferromagnetic layer is iron manganese, and the spacer layer is aluminum oxide. Note, the order of the AFM/FM layers may be reversed to insure this occurs; for example, a spintronic device employing a pinned ferromagnetic layer may have the following structure: Co/Al₂O₃/Co/FeMn.

A further improvement in the pinned ferromagnetic structure was found through the use of a synthetic antiferromagnet. In this architecture, the simple antiferromagnetic layer is replaced by a multilayer stack consisting of an antiferromagnetic layer (e.g. FeMn), a first ferromagnetic layer (e.g. Co), then a thin nonmagnetic spacer such as ruthenium (Ru). This multilayer structure is then followed by a second ferromagnetic layer which is in direct contact with both the spacing layer in the pinned ferromagnetic structure as well as the spacing layer included in an actual spintronic device. In the synthetic antiferromagnetic structure, the spacer layer (e.g. Ru) is chosen to be of a thickness to allow antiparallel coupling between the two ferromagnetic layers in the pinned structure. Thus, a typical spintronic device employing a pinned ferromagnetic layer by means of a synthetic antiferromagnet may have the following structure: FeMn/Co/Ru/Co/Al₂O₃Co.

Traditional spintronic devices are comprised of inorganic layers, including the ferromagnetic electrodes and the nonmagnetic layer which acts as the spacer between them. Some examples of inorganic nonmagnetic spacers are copper, silver, and aluminum oxide (Al₂O₃). Recent work has investigated the possibility of using organic layers as the spacer between the ferromagnetic electrodes. Besides being inexpensive and easy to fabricate, an organic layer is comprised primarily of carbon and other lightweight atoms leading to a weak spin-orbit interaction. This weak spin-orbit interaction will reduce the chance of electron spin coherence loss for current traveling between the ferromagnetic electrodes.

Previous work with organic spacer layers includes using organic semiconductor thin films of α-sexithiophene (6T) (see, V. Dediu, M. Murgia, F. C. Matacofta, and C. Taliani, Room Temperature Spin Polarized Injection in Organic Semiconductor, Solid State Commun. 122, 181-184 (2002), which is incorporated herein by reference in its entirety) as the spin transporting layer in a spin-valve operating at room temperature. The spin coherence length of 6T was reported to be 200 nm. Recently the spin-valve effect was established for another organic material, aluminum tris(8-hydroxyquinoline) (Alq₃), giving a spin coherence length of 45 nm at 11 K. (See, Z. H. Xiong, D. Wu, Z. V. Vardeny, and J. Shi, Giant Magnetoresistance in Organic Spin-Valve, Nature (London) 427, 821-824 (2004), which is incorporated herein by reference in its entirety.) This lower value, which is less than that for 6T is perhaps due to the presence of the Al atom.

A particularly attractive candidate for the nonmagnetic spacer layer is a third class of materials based on carbon nanotubes (CNTs). See, M. S. Dresselhaus, G. Dresselhaus, and P. Avouris (Eds.), Carbon Nanotubes, Springer, Berlin, 2001, which is incorporated herein by reference in its entirety. CNTs, as referred to herein, comprise single-walled CNTs and multi-walled CNTs, unless otherwise specified. For a number of reasons, extremely long spin coherence length is expected in CNTs. First, they possess weak electron-phonon scattering due to the very large stiffness of the CNT lattice. See, D. H Cobden, M. Bockrath, and P. L. McEuen Spin Splitting and Even-Odd Effects in Carbon Nanotubes, Phys. Rev. Lett. 81, 681-684 (1998), which is incorporated herein by reference in its entirety. As a result, the spin-lattice relaxation time, which is the limiting factor of the spin-scattering length, is very long. Second, in contrast to the hopping transport in most of the polymers, the electron motion in CNTs is coherent because of a very rigid and almost perfect lattice. Third, like traditional organic materials, CNTs have a very weak spin-orbit coupling. Fourth, unlike traditional organic materials that have atoms such as H in addition to the C atoms, CNTs have only C atoms resulting in very small or no hyperfine interaction (hyperfine interaction is zero for C¹², the overwhelmingly predominant weight of carbon).

The first measurement of spin dependent transport (SDT) of an individual CNT was made of Tsukagoshi (see, K. Tsukagoshi, B. W. Alphenaar, and H. Ago, Coherent Transport of Electron Spin in a Ferromagnetically Contacted Carbon Nanotube, Nature (Lond.) 401, 572-574 (1999), which is incorporated herein by reference in its entirety) and they estimated the spin-scattering length as at least 130 nm. Since the initial discovery of SDT in CNTs, other groups have continued the work on individual multi-walled or single-walled tubes, enhancing the effect and increasing usable temperature range to 175 K. See, C. M. Schneider, B. Zhao, R. Kozhuharova, S. Groudeva-Zotova, T. Muhl, M. Ritschel, I. Monch, H. Vinzelberg, D. Elefant, A. Graff, A. Leonhardt, and J. Fink, Towards Molecular Spintronics: Magnetotransport and Magnetism in Carbon Nanotube-Based Systems, Diamond and Related Materials 13, 215-220 (2004); B. Zhao, I. Monch, T. Muhl, H. Vinzelberg, and C. M. Schneider, Spin-Coherent Transport in Ferromagnetically Contacted Carbon Nanotubes, Appl. Phys. Lett. 80, 3144-3146 (2002); B. Zhao, I. Monch, T. Muhl, H. Vinzelberg, and C. M. Schneider, Spin-Dependent Transport in Multiwalled Carbon Nanotubes, J. Appl. Phys. 91, 7026-7028 (2002); S. Chakraborty, K. M. Walsh, B. W. Alphenaar, L. Liu, K. Tsukagoshi, Temperature-Mediated Switching of Magnetoresistance in Co-Contacted Multiwall Carbon Nanotubes, App. Phys. Lett. 83, 1008-1010 (2003); and, Jae-Ryoung Kim, H. Mi So, Ju-Jin Kim, and Jinhee Kim, Spin-Dependent Transport Properties in a Single-Walled Carbon Nanotube with Mesoscopic Co Contacts, Phys. Rev. B 66, 233401-(1-4) (2002), all of which are incorporated herein by reference in their entirety.

At present, all CNT spintronic devices utilize contacting an individual nanotube, both single- and multi-walled. The device then consists of the ferromagnetic contacts, separated by an individual CNT, whether it be single- or multi-walled. Such devices would be impractical to commercialize, as fabrication requires locating each nanotube separately and contacting it separately. A need exists to develop CNT based spintronic devices which may be fabricated and developed for large scale production.

Advances in CNT processing have allowed the fabrication of aligned arrays of nanotubes, both vertical and horizontal. See, S. Huang, L. Dai, and A. W. H. Mau, Patterned Growth and Contact Transfer of Well-Aligned Carbon Nanotube Films, J. Phys. Chem. B 103, 42234227 (1999); and, L. Dai, A. Patil, X. Gong, Z. Guo, L. Liu, Y. Liu, and D. Zhu, Aligned Nanotubes, Chem. Phys. Chem. 4, 1150-1169 (2003), both of which are incorporated herein by reference in their entirety. Further, it has been shown that the tubes may be embedded in a silicon dioxide matrix then polished, exposing the tips of the CNTs to improve mechanical stability and provide an opportunity to better make electrical contact to the tips of the nanotubes. See, J. Li, R. Stevens, L. Delzeit, H. T. Ng, A. Cassell, J. Han, and M. Meyyappan, Electronic Properties of Multiwalled Carbon Nanotubes in an Embedded Vertical Array, Appl. Phys. Lett. 81, 910-912 (2002), which is incorporated herein by reference in its entirety. In addition, the CNT arrays may also be patterned with small features using standard lithographic techniques. The use of arrays offers an opportunity for large scale production of CNT based devices.

### SUMMARY OF THE INVENTION

In one aspect, the present invention provides spintronics device architectures comprising arrays of more than one CNT as the nonmagnetic spacer.

In another aspect, the present invention provides spintronics device architectures comprising vertically aligned arrays of more than one CNT as the nonmagnetic spacer.

In still another aspect, the present invention provides a CNT based spintronic device that may operate at room temperature or above.

In an even further aspect, the present invention provides a CNT based spintronic device which utilizes the magnetic catalyst particle as one or more magnetic layers in the device architecture.

In yet another aspect, the present invention provides a spintronic device comprising a) a first conducting electrode operative to facilitate electrical contact, b) a first ferromagnetic layer disposed on the first conducting electrode operative to behave as a spin polarizer in order to inject electrons with a specific spin orientation, c) an array of carbon nanotubes (CNTs) disposed on the first ferromagnetic layer, d) a second ferromagnetic layer operative to behave as a spin analyzer in order to observe a high and low resistance state in the spintronic device wherein the array is operative to act as a spacer layer between the first and second ferromagnetic layers and to allow transport of injected electrons without complete loss of spin orientation, and e) a second conducting electrode disposed on the second ferromagnetic layer operative to facilitate electrical contact. Ferromagnetic layer includes both one hundred percent spin polarized ferromagnetic layer and less than 100 percent spin polarized layer.

In yet a further aspect, the present invention provides a method for forming a spintronic device comprising forming a first electrode, forming a first ferromagnetic layer on the first electrode, forming a vertically aligned carbon nanotube array on the first ferromagnetic layer, forming a second ferromagnetic layer, and forming a second electrode on the second ferromagnetic layer.

### BRIEF DESCRIPTION OF THE DRAWINGS

Embodiments of the present invention exists in the construction, arrangement, and combination of the various parts of the device, and steps of the method, whereby the objects contemplated are attained as hereinafter more fully set forth, specifically pointed out in the claims, and illustrated in the accompanying drawings in which:

FIG. 1 is an illustrative view of an embodiment of the present invention;

FIG. 2 is a graph showing results of an implementation of the present invention;

FIG. 3 is a graph showing results of an implementation of the present invention; and,

FIG. 4 is a graph showing results of an implementation of the present invention.

### DETAILED DESCRIPTION OF THE INVENTION

The present invention relates to a multilayered hybrid magnetic/CNT device. A multilayered hybrid magnetic/CNT device in accordance with the present disclosure includes an aligned array of CNTs sandwiched between ferromagnetically behaving layers which act as a spin polarizer and analyzer, respectively.

The ferromagnetic layers may comprise any ferromagnetic material suitable for use in a spintronic device. It will be understood that reference to ferromagnetic materials also includes ferromagnetic materials herein. The ferromagnetic layers may individually comprise a single layer of a ferromagnetic material or multiple layers, e.g., 2, 3, 4, or more layers, in a stacked configuration. In one embodiment, the ferromagnetic layers may comprise multiple stacked layers which act as a ferromagnet such as, for example, a pinned ferromagnet comprising a ferromagnetic layer followed by either an antiferromagnetic layer, or a synthetic antiferromagnet comprising of an antiferromagnet/ferromagnet/nonmagnet trilayer. Further, in another embodiment, one or more of the ferromagnetic layers may comprise a synthetic antiferromagnet having two ferromagnetic layers separated by a spacer of suitable composition and thickness with one of the ferromagnetic layers contacting an antiferromagnetic layer to improve the stability and increase the switching field of the spintronic device. In other embodiments the ferromagnetic layers may independently be fully or partially spin polarized. Suitable spacer compositions include, but are not limited to, arrays of single wall CNTs, arrays of multiwall CNTs, arrays containing both single wall and multiwall CNTs. The single wall CNTs may be metallic or semiconducting in properties. Each of the CNT concentric walls that comprise each of the multiwall CNTs may independently be metallic or semiconducting in properties. The thickness of the spacer may be selected as desired for a particular purpose. Generally, the CNT array spacer may have a thickness in the range of from about several hundred nanometers to about several millimeters. Additionally, the ferromagnetic layers need not be in the form of thin films, but can include ferromagnetic particles used in the synthesis of the CNT array. In another embodiment, the ferromagnetic particles may be the catalyst for the growth of the carbon nanotubes. In still a further embodiment, the magnetic layer(s) may include a patterned grid of differing magnetic electrodes which allows the device to have various switching fields and differing resistance under different magnetic histories. One or more of the first and second ferromagnetic layers may also comprise a patterned grid of ferromagnetically behaving islands of differing composition (such as, for example, nickel, chromium, cobalt, or their alloys) so that the resulting ferromagnetic contact to any CNTs that grow from these islands switches in different magnetic fields and is transmissive to electrons, holes, or both. Moreover, the magnetic layer may be composed of an organic rather than inorganic magnetic material such as, for example, vanadium tetracyanoethylene (V(TCNE)₋₂) or a vanadium-metal composition with TCNE (VₓM₁₋ₓ(TCNE)₋₂) where M is including but not limited to Fe, Co, Ni, Cr, and Mn.

Electrical contact to a present multilayered hybrid magnetic/CNT device may be made by an electrode using any suitable material. Examples of suitable materials include, but are not limited to: i) a suitable electrically conducting electrode comprising an inorganic metal, e.g. Au, Cu, Ag, Al; ii) a conducting polymer such as, for example, camphor sulfonic acid dope polyaniline (PANi-CSA) or polystyrene sulfonic acid doped polyethylenedioxythiophene (PEDOT-PSS); iii) a doped semiconductor such as p-doped silicon, etc.; and the like.

Thus, a device in accordance with the present disclosure is a multilayered structure comprising a bottom electrically conductive electrode, a ferromagnetic layer suitable for use as a spin polarizer (to inject electrons with a specific spin orientation), a CNT array as a non-magnetic spacing layer (which allows the transport of injected electrons without complete loss of spin orientation—e.g., a high percentage of spin orientation such 99% or 95% may be retained or a lower percentage of spin orientation such as 50%, 10% or 1% may be retained), a ferromagnetic layer suitable for use as a spin analyzer (to observe a high and low resistance state of the spintronic device), and a top electrically conductive electrode.

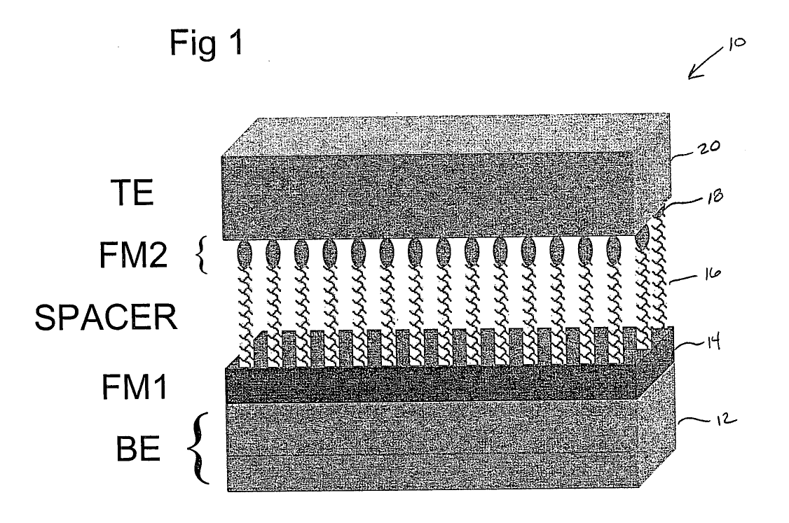

An additional consideration which arises in the use of a CNT array in the present type of architecture is the method of creating electrical contact between the CNT array and the preceding/subsequent layers. In accordance with the present invention, a CNT array may be electrically connected to one of the first and second ferromagnetic layers by a contact including, but not limited to, a pressure contact, a laminated contact, direct deposition of the ferromagnetic layer onto the CNT array and the like. Such contacts are also referred to herein as mechanical contacts. In one embodiment, as shown in FIG. 1, a pressure contact may be used with heating of the layers to enhance bonding. In another embodiment, the electrical contact between a CNT and a preceding or subsequent layer is a laminated contact in which the layers to be bonded to the CNT array are deposited on a suitable elastomer that will provide atomic contact between the layers and the CNT array with the stickiness of the elastomer and keep them in close and constant contact. Other examples of suitable elastomers for forming a laminated contact include, but are not limited to, Viton and Neoprene. An example of a suitable elastomer for forming a laminated contact includes PDMS. In still another embodiment, which may be the best method, electrical contact is made by direct deposition of one of the preceding or subsequent layers onto the CNT array. The ability to use direct deposition depends on several factors such as the ability to satisfactorily grow the CNT array on the layers which must precede it and the density of packing of the nanotubes in the array after their deposition which will determine if a subsequent layer can be deposited.

If the density is insufficient, either a mechanical contact must be made as above, or the array can be embedded in another insulating material to fill the voids which would create shorts if a deposition occurred on top of the CNT array. This results in mechanical stability and improved electrical contact. The insulating material (also referred to as insulators) may be selected from an inorganic insulating material or an organic insulating material. Examples of suitable inorganic insulating materials include, but are not limited to, SiO₂, Al₂O₃, and the like. For example, one such method of embedding the array was discussed above by embedding in a suitable inorganic insulated material such as SiO₂. In this method, the entire array is covered by SiO₂, a mechanical polishing step follows which uncovers the tips of the tubes. In this manner, a solid layer is formed with the electrical contact possible to the tips of the CNTs in the array. Likewise, in another embodiment, Al₂O₃ may be used as an inorganic insulator. Alternatively, the array may be embedded in an organic insulator including, but not limited to, pentacene, Alq₃ or carbazole with the tubes then uncovered by a slow annealing process which should remove the organic insulator preferentially from the exposed tips, rather than from within the voids.

Referring to FIG. 1, an exemplary spintronic multilayered device 10 according to the present application is illustrated. It will be appreciated that the device depicted in FIG. 1 and the description and formation thereof is merely exemplary and that other embodiments thereof are possible. As shown, the device 10 comprises a chromium (Cr)/gold (Au) bilayer 12 as the bottom electrode (also depicted as BE), an iron (Fe) cobalt (Co) binary alloy (FeCo) layer 14 as the first ferromagnetic layer (also depicted as FM1), a vertically aligned array of multi-walled carbon nanotubes as the nonmagnetic spacer 16 (also denoted as SPACER), embedded catalytic Fe nanoparticles—which remain after deposition of the CNT array—serving as a second ferromagnetic layer 18 (also depicted as FM2) and a gold layer 20 serving as the top electrode (also depicted as TE). Of course, although not specifically shown, those skilled in the art will appreciate that the top and bottom electrodes, which are operative to facilitate electrical contact, may be suitably connected to electronic driving and measurement circuits in any suitable manner using any suitable technique or means. The termination as FM1 and FM2 is of course interchangeable, with the layer marked as FM1 being considered as FM2 and the layer being marked as FM2 then being considered as FM1.

The CNT array may be formed from any suitable material that may be formed into a carbon nanotube and allows for the transport of injected electrons without complete loss of spin orientation. Examples of materials suitable for forming a CNT in the CNT array include, but are not limited to, iron (II) phthalocyanine, thermal decomposition of ethylene over a thin layer of iron, hot filament plasma enhanced chemical vapor deposition first coated with nickel or iron nanoparticles, and the like.

The CNT array may comprise, in one embodiment, multi-walled carbon nanotubes (MWCNTs). Alternatively, in another embodiment, the CNT array may be formed of single-walled CNTs (SWCNTs). In still another embodiment, a CNT array may comprise both multi-walled and single-walled CNTs.

It should be further appreciated that the CNT array may comprise conducting CNTs, semi-conducting CNTs, or both conducting and semi-conducting CNTs. In one embodiment, a CNT array may comprise greater than about 90% conducting CNTs and less than about 10% semi-conducting CNTs. In another embodiment, a CNT array may comprise greater than about 90% semi-conducting CNTs and less than about 10% conducting CNTs.

Moreover, it should be appreciated that the CNT array may take the form of a vertical or non-vertical array of CNTs formed by a variety of processes. For example, the CNT array may be a vertical array of CNTs formed by pyrolysis of iron (II) pthalocyanine. A vertical array may also be formed using a nanoporous template. Further, a vertical array may be formed by CVD of acetylene, or similar carbon-based gas on a ferromagnetic film.

A spintronic device may be formed by forming a first electrode, forming a first ferromagnetic layer over the electrode, forming a CNT array on the first ferromagnetic layer, forming a second ferromagnetic layer, and forming a second electrode on the second ferromagnetic layer. The first electrode may be formed by any deposition method suitable for the material selected as the electrode including, for example, thermal evaporation. A CNT array may be formed by, for example, pyrolysis of iron (II) phthalocyanine on a substrate. The conditions of the CNT deposition are controlled such that the embedded iron catalyst particle is at the desired location, e.g., the top or bottom, after deposition. The top electrode is then applied using any available deposition technique such as, for example, sputtering.

A spintronic device having a configuration in accordance with the embodiment depicted in FIG. 1 was prepared as follows. Metallic layers (12 and 14) were formed with a thermal evaporation technique. A 10 nm layer of Cr was deposited on the glass substrate to serve as an adhesion layer for subsequent depositions. The Cr layer was followed by a deposition of Au of 35 nm thickness to provide a sufficient electrical connection. The next layer formed was the first ferromagnetic layer comprising a FeCo alloy which was deposited over a portion of the Au such that electrical contact to the measuring instruments could be made directly to the Au, rather than the less stable FeCo. The thickness of the FeCo layer was 8 nm, with the alloy being a result of a co-deposition of Fe (99.9+%, Aldrich) and Co (99.9+%, Aldrich) at a deposition rate of 0.12 nm/second.

A vertically aligned CNT array (16) was formed by pyrolysis of iron (II) phthalocyanine under argon/hydrogen at 800-1000° C. on a quartz substrate. The resulting array is a mixture of semiconducting and conducting multi-walled CNTs. The lengths of the CNTs can be controlled from ˜1 μm to over 10 μm, the length of CNTs in the device described with reference to FIG. 1 was about 7 μm. The deposition conditions were held such that the embedded Fe catalyst particle was at the top (tube end farthest from the quartz substrate) after deposition, thus providing a second ferromagnetic layer (18). After deposition of the CNT array, a top electrode (20) of Au was deposited by a sputtering technique, the thickness was large in order to have mechanical strength after the liftoff procedure. Following the deposition of Au, the quartz substrate was dipped (for approximately 10-20 seconds) in a hydrofluoric acid/water mixture. The acid quickly causes the CNT/Au film to be removed from the quartz substrate, creating a free standing film.

The CNT/Au film was then cut to an appropriate size and placed on the glass substrate such that the CNTs directly contacted the FeCo layer. Electrical contact was enhanced by heating the substrate to ˜150° C. in a vacuum oven for one hour. Electrical contact was then made to the Au electrodes, and the device was encapsulated with teflon tape for protection.

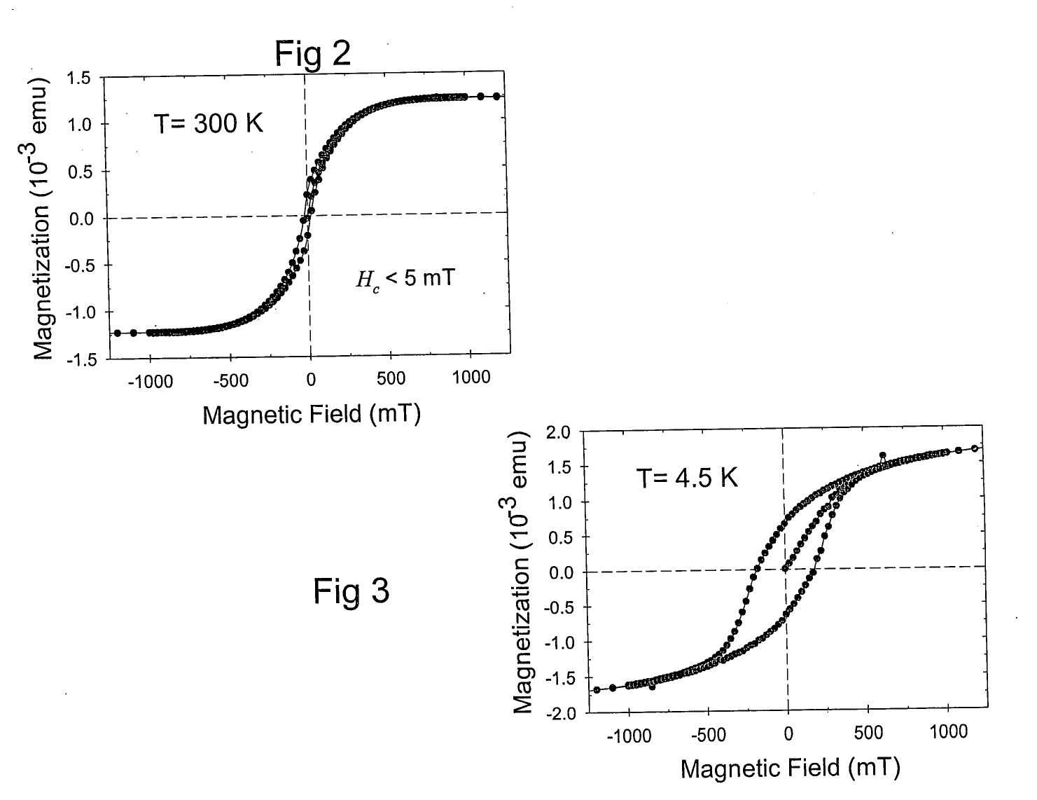

Magnetic data of the CNTs in accordance with the embodiment of FIG. 1 was performed on a Quantum Design MPMS-5 SQUID magnetometer. The results (FIGS. 2 and 3) show that the Fe catalyst particles present at the tips of the CNT array are ferromagnetic at room temperature (300 K) and show a sizeable hysteresis at lower temperatures (e.g., 4.5 K).

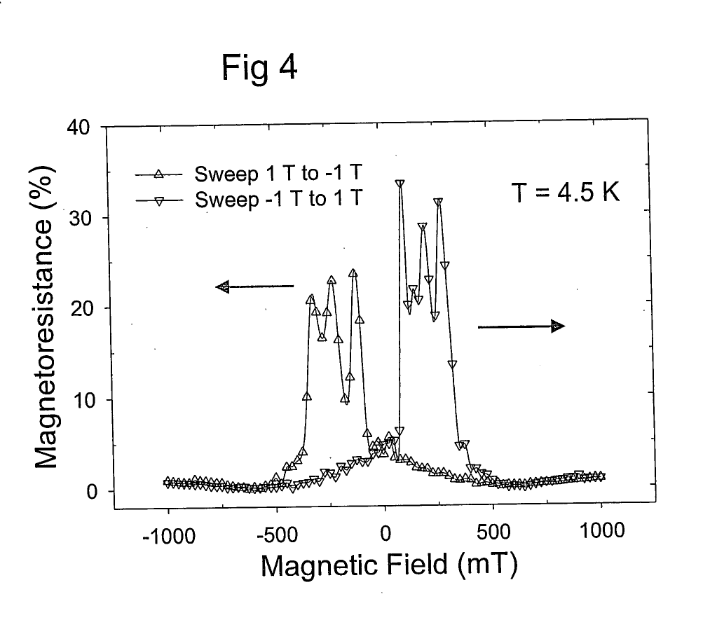

FIG. 4 shows the magnetoresistance of the above device of FIG. 1 at 4.5 K. The data were taken on a Quantum Design PPMS-9 measurement system. The resistance data were taken with a bias voltage of 95 mV over a magnetic field range of 1 Tesla to −1 Tesla in both directions (+1 to −1 and −1 to +1). The results show a hysteretic effect typical in spin valve type structures. After crossing zero magnetic field from +1 T, the resistance increases as the magnetization direction in the FeCo film switches sign from positive to negative. The resistance then reduces to the previous lower value near 500 mT, consistent with the value observed from magnetic data in FIG. 3, as the magnetization direction of the Fe nanoparticles embedded in the CNT array switches sign from positive to negative. A similar effect is seen as the field is swept from −1 T to +1 T.

It will be understood by those of skill in the art that the present invention relates to spintronic devices such as, for example, spin valves, spin tunnel junctions, spin light emitting diodes, GMR resistance elements and MRAM devices. As such, the present invention may be applied to spintronic devices operating in such environments.

Spintronic devices in accordance with the present disclosure have been described with reference to an exemplary embodiment and examples. It is possible, however, that changes in configurations to other than those shown could be used. Without departing from the spirit of this invention, various means of fastening the components together may be used.

It is therefore understood that, although the present invention has been specifically disclosed with reference to an exemplary embodiment and specific examples, modifications to the design concerning sizing and shape will be apparent to those skilled in the art and such modifications and variations are considered to be equivalent to and within the scope of the disclosed invention and the appended claims.

It is to be understood that, although the present invention has been specifically disclosed with reference to an exemplary embodiment and examples, modifications to the experimental design may be apparent to those skilled in the art and such modifications and variations are considered to be within the scope of the invention and the appended claims.

It is also intended that all matter contained in the above description shall be interpreted as illustrative and not in a limiting sense, the scope of the invention being indicated by the appended claims rather than by the foregoing description, and all changes that come within the meaning and range of equivalency of the claims are therefore intended to be embraced therein. That is, the following claims are intended to cover all of the generic and specific features of the invention herein described, and all statements of the scope of the invention which, as a matter of language, fall there between. Furthermore, it is to be understood that in the following claims, ingredients or compounds recited in the singular are intended to include compatible mixtures of such ingredients wherever the sense permits.

We claim:

1. A spintronic device comprising:
a) a first conducting electrode operative to facilitate electrical contact;
b) a first ferromagnetic layer disposed on the first conducting electrode operative to behave as a spin polarizer in order to inject electrons with a specific spin orientation;
c) an array of carbon nanotubes (CNT's) disposed on the first ferromagnetic layer;
d) a second ferromagnetic layer operative to behave as a spin analyzer in order to observe a high and low resistance state in the spintronic device wherein the array is operative to act as a spacer layer between the first and second ferromagnetic layers and to allow transport of injected electrons without complete loss of spin orientation; and,
e) a second conducting electrode disposed on the second ferromagnetic layer operative to facilitate electrical contact.

2. The spintronic device of claim 1 wherein at least one of the first and second ferromagnetic layers comprise embedded ferromagnetic catalyst particles remaining after deposition of the CNT array.

3. The spintronic device of claim 1 wherein the CNT array is embedded in a suitable inorganic insulator in order to facilitate mechanical stability and electrical contact.

4. The spintronic device of claim 1 wherein the CNT array is embedded in a suitable organic insulator in order to facilitate mechanical stability and electrical contact.

5. The spintronic device of claim 1 wherein the CNT array comprises multi-walled CNTs.

6. The spintronic device of claim 1 wherein the CNT array comprises single-walled CNTs.

7. The spintronic device of claim 1 wherein the CNT array is a vertical array of CNTs formed by pyrolysis of iron (II) pthalocyanine.

8. The spintronic device of claim 1 wherein the CNT array is a vertical array of CNTs formed using a nanoporous template.

9. The spintronic device of claim 1 wherein the CNT array is a vertical array of CNTs formed by CVD of acetylene, or a carbon based gas on a ferromagnetic film.

10. The spintronic device of claim 1 wherein the CNT array comprises a mixture of both conducting and semiconducting CNTs.

11. The spintronic device of claim 1 wherein the CNT array comprises over 90% conducting CNTs and less than 10% semiconducting CNTs.

12. The spintronic device of claim 1 wherein the CNT array comprises over 90% semiconducting CNT's and less than 10% conducting CNTs.

13. The spintronic device of claim 1 wherein at least one of the first and second ferromagnetic layers comprise an antiferromagnetic layer and a ferromagnetic layer forming a ferromagnetic layer pinned by exchange bias.

14. The spintronic device of claim 1 wherein at least one of the first and second ferromagnetic layers comprise a synthetic antiferromagnet having two ferromagnetic layers separated by a spacer of suitable composition and thickness with one of the ferromagnetic layers contacting an antiferromagnetic layer to improve the stability and increase the switching field of the spintronic device.

15. The spintronic device of claim 1 wherein at least one of the first and second ferromagnetic layers comprise a patterned grid of ferromagnetically behaving layers.

16. The spintronics device of claim 1 wherein at least one of the first and second ferromagnetic layers comprise a patterned grid of ferromagnetically behaving islands of differing composition so that the resulting ferromagnetic contact to the CNTs that grow from these islands switch in different magnetic fields.

17. The spintronic device of claim 1 wherein the device is operated as a spin valve.

18. The spintronic device of claim 1 wherein the device is operated as a spin tunnel junction.

19. The spintronic device of claim 1 wherein the device is operated as a spin LED.

20. The spintronic device of claim 1 wherein the device is operated as a GMR resistance element.

21. The spintronic device of claim 1 wherein the device is operated as a component of MRAM devices.

22. The spintronic device of claim 1 further comprising means for electrically connecting the first ferromagnetic layer to the CNT array and the CNT array to the second ferromagnetic layer.

23. The spintronic device of claim 22 wherein the connection means comprises a pressure contact.

24. The spintronic device of claim 22 wherein the connection means comprises a laminated contact using a suitable elastomer such as PDMS.

25. The spintronic device of claim 22 wherein the connection means comprises a direct deposition to the CNT array.

26. The spintronic device of claim 1 further comprising means for connecting the first and second conducting electrodes to at least one of electronic driving and measurement circuits.

27. A method for forming a spintronic device comprising:
forming a first electrode;
forming a first ferromagnetic layer on the first electrode;
forming a vertically aligned carbon nanotube array on the first ferromagnetic layer;
forming a second ferromagnetic layer; and,
forming a second electrode on the second ferromagnetic layer.
